(19) United States
(12) Patent Application Publication
(10) Pub. No.: US 2026/0293592 A1
(43) Pub. Date: Sep. 24, 2026

(54) TRANSPORT SYSTEM AND TRANSPORT METHOD

(71) Applicant: Tokyo Electron Limited, Tokyo (JP)

(72) Inventors: Yusuke NATORI, Yamanashi (JP); Jun FUJIHARA, Yamanashi (JP); Tomoya ENDO, Yamanashi (JP)

(21) Appl. No.: 19/670,104

(22) Filed: May 7, 2026

Related U.S. Application Data
(63) Continuation of application No. PCT/JP2024/039273, filed on Nov. 5, 2024.

(30) Foreign Application Priority Data
Nov. 17, 2023 (JP) 2023-196187

(51) Int. Cl. H10P 72/30; H10P 72/00; H10P 72/50; H10P 72/76

(52) U.S. Cl. CPC H10P 72/3202; H10P 72/0606; H10P 72/50; H10P 72/7602; H10P 72/7612; H10P 72/7618

(57) ABSTRACT

A transport system includes: a transport module extending in the first direction; a plurality of processing modules connected to the transport module; and a transport device provided inside the transport module and configured to transport a transport target to the plurality of processing modules. The transport device includes: a moving mechanism configured to move the transport target along the first direction; a lower slider provided above the moving mechanism in a vertical direction and capable of moving the transport target in a second direction different from the first direction; and an upper slider provided above the lower slide part in the vertical direction and capable of moving the transport target in the second direction.

### CROSS-REFERENCE TO RELATED APPLICATIONS

This application is a continuation application of International Application No. PCT/JP2024/039273, filed on Nov. 5, 2024, and designating the U.S., which is based upon and claims priority to Japanese Patent Application No. 2023-196187 filed on Nov. 17, 2023, the entire contents of which are incorporated herein by reference.

### BACKGROUND

### Technical Field

The present disclosure relates to a transport system and a transport method.

### Background Art

Japanese Patent Application Laid-Open Publication No. 2016-72356 discloses an inspection system including a transport device for transporting a substrate (wafer). In this transport device, a transport arm for supporting a substrate is housed inside a cover. The transport device launches the transport arm from the cover into an inspection part of the inspection unit, such that the substrate is passed over and received between the transport arm and the inspection part.

### SUMMARY

According to one aspect of the present disclosure, a transport system is provided, including: a transport module extending in a first direction; a plurality of processing modules connected to the transport module; and a transport device provided inside the transport module and configured to transport a transport target to the plurality of processing modules, wherein the transport device includes: a moving mechanism configured to move the transport target along the first direction; a lower slider provided above the moving mechanism in a vertical direction and capable of moving the transport target in a second direction different from the first direction; and an upper slider provided above the lower slider in the vertical direction and capable of moving the transport target in the second direction.

### BRIEF DESCRIPTION OF THE DRAWINGS

FIG. 1 is an enlarged plan view of a transport system according to an embodiment;

FIG. 2 is an enlarged oblique view of an X-axis negative side of a transport module and an inspection device;

FIG. 3 is a schematic side view showing an installation state of a transport module including a transport device and of an inspection device;

FIG. 4 is an enlarged side view of a transport device;

FIG. 5 is an oblique view showing an advancing/retreating moving mechanism of a transport device;

FIG. 6 is a flowchart showing a method of transporting a substrate in a transport module;

FIG. 7A is a side view showing a state in which an open part of a transport device faces a target inspection device;

FIG. 7B is a side view showing an advancing state of a lower slider of a transport device; and

FIG. 7C is a side view showing an advancing state of an end effector of an upper slider of a transport device.

### DETAILED DESCRIPTION OF THE INVENTION

Hereinafter, embodiments of the present disclosure will be described with reference to the drawings. In the drawings, the same components are denoted by the same reference numerals and redundant descriptions may be omitted.

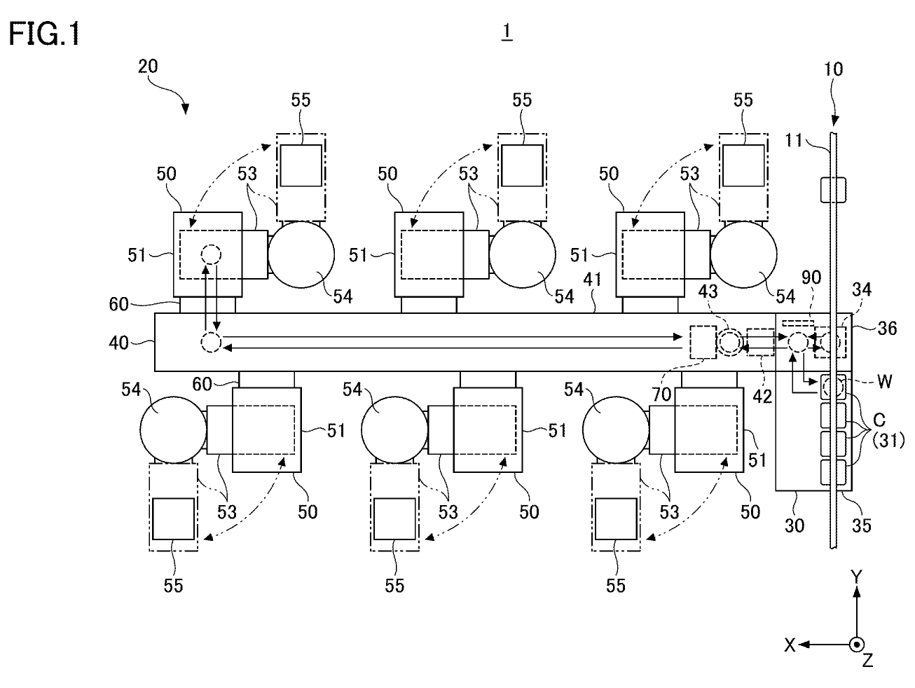

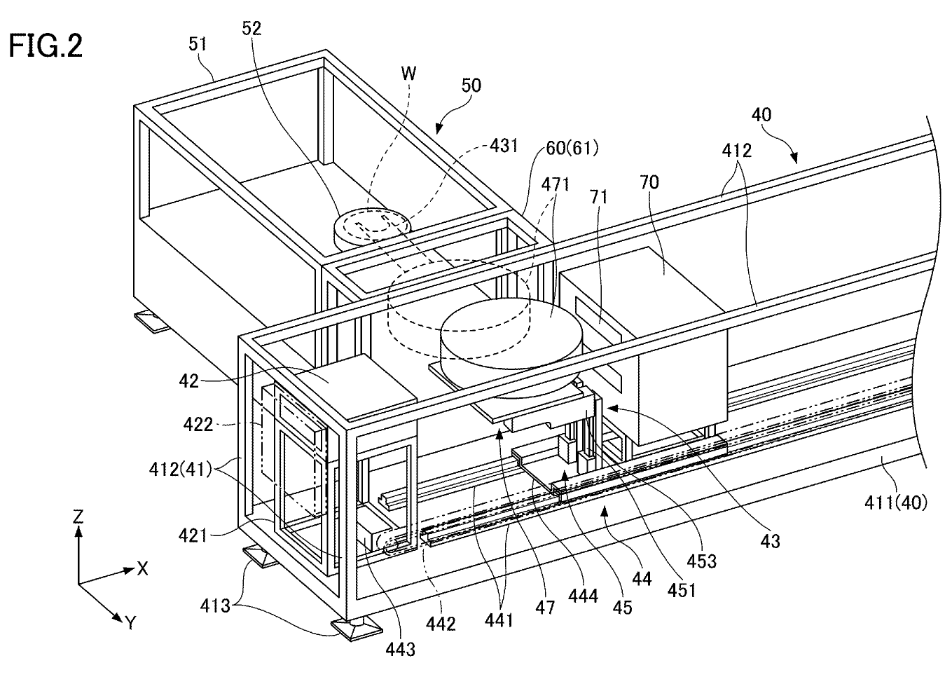

FIG. 1 is an enlarged plan view showing a transport system 1 according to an embodiment. As shown in FIG. 1, the transport system 1 is constructed at a work area, such as a facility for manufacturing semiconductors, a facility for inspecting semiconductors, and the like. In an embodiment, a transport system 1 for transporting a substrate W to an inspection device 50 for inspecting the substrate W (see FIG. 2) will be described. An example of the substrate W to be inspected is a wafer (wafer under test) on which a plurality of semiconductor devices, which are each a Device Under Test (DUT) to be inspected, are arranged in a matrix. The substrate W is not limited to a wafer, and may be a carrier, a glass substrate, a single chip, an electronic circuit board, and the like having a semiconductor device.

The transport system 1 includes an Overhead Hoist Transport (OHT) 10 for transporting a carrier C and a plurality of substrate inspection units 20. The carrier C is a container capable of housing a plurality of (for example, 25) substrates W. An example of the carrier C is a Front Opening Unified Pod (FOUP) having one side surface openable and closable. The overhead hoist transport 10 transports the carrier C that is in a state of housing a plurality of substrates W or in an empty state.

The overhead hoist transport 10 includes a rail 11 fixed to the ceiling of a work area, and a hoist mechanism (not shown) that can move along the rail 11 while holding the carrier C and can raise and lower the carrier C. For example, the hoist mechanism has a function of holding the carrier C in a suspended manner, and raising and lowering the carrier C by a belt. The overhead hoist transport 10 includes a control device (not shown) for controlling the operation of the overhead hoist transport 10 at an appropriate position in the work area.

The rail 11 is installed to pass above a loader module 30 of each substrate inspection unit 20. The hoist mechanism moving along the rail 11 can automatically set the carrier C in the loader module 30 by moving to immediately above the loader module 30 of the target substrate inspection unit 20 and lowering the carrier C. Conversely, the hoist mechanism can unload the carrier C from the substrate inspection unit 20 by moving to immediately above the carrier C of the loader module 30 and holding and raising the carrier C.

The control device moves the hoist mechanism to a target position on the rail 11 and controls raising or lowering, holding, releasing, and the like of the carrier C. The control device controls a carrier exchange unit (not shown) provided on the rail 11 to perform recovery, exchange, and the like of the carrier C, and manages the state of each substrate W in the carrier C. The control device may be annexed to a management computer for managing the entire transport system 1 (work area).

On the other hand, each substrate inspection unit 20 of the transport system 1 is installed to extend in a direction orthogonal to the direction in which the rail 11 installed in the work area extends.

By including a plurality of modules in combination, each substrate inspection unit 20 is constructed as a unit for efficiently transporting each substrate W from the carrier C and performing inspection of the substrate W. Specifically, each substrate inspection unit 20 includes the loader module 30, a transport module 40 connected to the loader module 30, and a plurality of inspection devices 50 connected to the transport module 40. Each substrate inspection unit 20 takes out a substrate W from the carrier C transported to the loader module 30 by the overhead hoist transport 10, transports the substrate W to an intended inspection device 50 via the transport module 40, and inspects the substrate W in the inspection devices 50.

In the description of the substrate inspection unit 20, positions and directions of each component will be described based on the directions of arrows shown in FIG. 1. The X-axis direction in FIG. 1 is the longer direction of the drawing sheet and is a direction along the direction in which the transport module 40 extends. The Y-axis direction in FIG. 1 is the shorter direction of the drawing sheet and is a direction along the direction in which the loader module 30 extends. The Z-axis direction in FIG. 1 is the depth direction of the drawing sheet, is the direction of the height of the substrate inspection unit 20.

The loader module 30 of the substrate inspection unit 20 is provided on the lower side of the rail 11 of the overhead hoist transport 10 in the vertical direction. The longer direction of the loader module 30 is along the Y-axis direction. In other words, the loader module 30 is installed such that the longer direction of the loader module 30 coincides with the direction in which the rail 11 extends. The loader module 30 has a plurality of (four in FIG. 2) load ports 31 capable of mounting a plurality of carriers C, respectively, in parallel along the Y-axis direction.

The load ports 31 of the loader module 30 receive carriers C from the hoist mechanism of the overhead hoist transport 10, and hand off the carriers C to the hoist mechanism. The carriers C mounted on the load ports 31 are fixed by engagement mechanisms (not shown) of the load ports 31.

The loader module 30 is internally provided with a loader-side transport device (not shown) for taking out a substrate W from the carrier C on each load port 31 and transporting it to the transport module 40. A path on which the loader-side transport device can move in the Y-axis direction is provided in the loader module 30. The loader module 30 may be configured to provide a downflow of clean air into the path.

The loader module 30 may also internally include an aligner device 34 for detecting the position and the circumferential-direction orientation (attitude) of the substrate W, and adjusting misalignment of the substrate W and the attitude of the substrate W in cooperation with the loader-side transport device. In the loader module 30 shown in FIG. 1, the aligner device 34 is provided on the Y-axis positive direction side and the X-axis negative direction side that are connected to the transport module 40.

The loader module 30 includes a main housing 35 having the load ports 31, and a sub-housing 36 formed separately from the main housing 35 and relaying the main housing 35 and the transport module 40 with each other. The main housing 35 and the sub-housing 36 are disposed side by side in the Y-axis direction. In the loader module 30, the internal frames of the main housing 35 and the sub-housing 36 may be formed separately, and a cover for covering the internal frames may be continuous to integrate them.

By assembling a plurality of frames (not shown), the main housing 35 is formed in a box having a rectangular shape when viewed in the X-axis direction and a letter-L shape when viewed in the Y-axis direction. The main housing 35 has the load ports 31 on the upper surface of the L-shaped stepped part.

By assembling a plurality of frames (not shown), the sub-housing 36 is formed in a rectangular parallelepiped shape having a rectangular shape longer in the X-axis direction and shorter in the Y-axis direction when viewed in a plan view, and having a predetermined height in the Z-axis direction. The sub-housing 36 is formed in a size smaller than the main housing 35. The aligner device 34 described above is provided inside the sub-housing 36. A controller 90 for controlling the operation of each component of the substrate inspection unit 20 is installed inside the sub-housing 36. Further, the sub-housing 36 is provided with a control panel (not shown) operable by a user on a side surface on the Y-axis positive direction side.

Of the two housings of the loader module 30 described above, the main housing 35 has versatility applicable to various substrate inspection units 20. That is, the same main housing 35 can be applied even when the type of substrate inspection unit 20 is changed. On the other hand, of the two housings of the loader module 30, the sub-housing 36 has customizability that allows the configuration and shape to be changed in accordance with the needs of each customer. For example, when a customer does not need the aligner device 34, the sub-housing 36 can be changed to specifications without the aligner device 34. By including the sub-housing 36 that is customizable and the main housing 35 that is, on the other hand, of the fixed standard, the loader module 30 can meet the needs of various customers while restricting the specifications change of the entire module.

The transport module 40 is connected to the side surface of the sub-housing 36 of the loader module 30 on the X-axis positive direction side, and extends linearly along the X-axis direction. That is, the direction in which the longer direction of the transport module 40 extends is orthogonal to the direction in which the longer direction of the loader module 30 extends. A plurality of (three) inspection devices 50 are connected on each side of the direction in which the transport module 40 extends (that is, on a side surface of the transport module 40 on the Y-axis positive direction side and on a side surface of the transport module 40 on the Y-axis negative direction side). Each of the inspection devices 50 is connected orthogonally (at an angle of 90°) to the transport module 40. However, each of the inspection devices 50 may be connected to the transport module 40 at an angle of, for example, approximately 45° to 90°.

The transport module 40 receives and hands off the substrate W from and to the loader module 30, transfers the substrate W to a target inspection device 50 among the plurality of inspection devices 50, and hands off and receives the substrate W to and from a stage 52 of the target inspection device 50.

Specifically, the transport module 40 includes a transport housing 41 extending in the X-axis direction, a buffer 42 provided on the X-axis negative direction side in the transport housing 41, and a transport device 43 reciprocating in the transport housing 41 along the X-axis direction. The transport module 40 may be a vacuum transport module for transporting the substrate W in a state where the transport space in the transport housing 41 is reduced to a vacuum atmosphere.

FIG. 2 is an enlarged oblique view showing the X-axis negative direction side of the transport module 40 and the inspection device 50. As shown in FIG. 2, the framework of the transport housing 41 is formed by assembling a base plate 411 and a plurality of frames 412. The transport housing 41 constructs a sealed transport space, with panels (not shown) attached to the base plate 411 and the plurality of frames 412.

The base plate 411 of the transport housing 41 is fixed to the floor of the work area via a plurality of legs 413. Each of the plurality of legs 413 has a level adjuster (not shown) capable of adjusting the height in the Z-axis direction. When installing the transport module 40, each level adjuster is adjusted such that the upper surface of the base plate 411 becomes a horizontal plane. An X-axis moving mechanism 44 of the transport device 43 is installed on the base plate 411 of the transport housing 41.

The X-axis moving mechanism 44 includes a pair of rails 441 extending on the base plate 411 in the X-axis direction, endless belts 442 extending on the side of the rails 441, a drive motor 443 provided at one end of paths of the belts 442, and an X-axis movable body 444 engaged with the belts 442. The X-axis movable body 444 bridges the pair of rails 441 and supports the components of the transport device 43 that are above the X-axis moving mechanism 44. The drive motor 443 is connected to the controller 90 (see FIG. 1) via a driver (not shown), and the drive force and the drive direction of the drive motor 443 are controlled by the controller 90. Thus, the drive motor 443 rotates the belts 442 in the forward direction or in the reverse direction. The X-axis movable body 444 reciprocates along the extending direction of the pair of rails 441 based on the rotation of the belts 442. The transport device 43 is not limited to the X-axis moving mechanism 44 including the belts 442 and the drive motor 443, and various mechanisms may be employed. As an example, the X-axis moving mechanism 44 may be configured to slide the X-axis movable body 444 by a linear motor.

On the other hand, the buffer 42 provided in the transport housing 41 is disposed at an appropriate height position by a table 421 mounted on the base plate 411. The buffer 42 temporarily houses the substrate W transported by the loader-side transport device of the loader module 30 and hands off the substrate W to the transport device 43. The buffer 42 also temporarily houses the substrate W transported by the transport device 43 and hands off the substrate W to the loader-side transport device. The buffer 42 may have a load lock function capable of switching the internal space between an open-air atmosphere and a vacuum atmosphere. Further, the buffer 42 may internally include an aligner capable of adjusting misalignment and the circumferential-direction orientation of the substrate W.

A gate valve 422 for opening and closing a port of the buffer 42 is provided on a side surface of the buffer 42 on the X-axis negative direction side. A gate valve may also be provided on a side surface on the X-axis positive direction side. The substrate inspection unit 20 can transport the substrate W between the loader module 30 and the buffer 42 by opening the gate valve 422 on the X-axis negative direction side, and can depressurize the interior of the transport module 40 including the buffer 42 by closing each gate valve 422. The substrate inspection unit 20 can transport the substrate W between the transport device 43 and the buffer 42 by opening the gate valve on the X-axis positive direction side.

The transport device 43 of the transport module 40 loads and unloads the substrate W into and from the buffer 42. The transport device 43 moves in the X-axis direction by means of the X-axis moving mechanism 44, to be located at a position facing an intended inspection device 50 among the plurality of inspection devices 50 connected to the transport module 40. Then, the transport device 43 advances into the facing inspection device 50 and loads and unloads the substrate W into and from the inspection device 50.

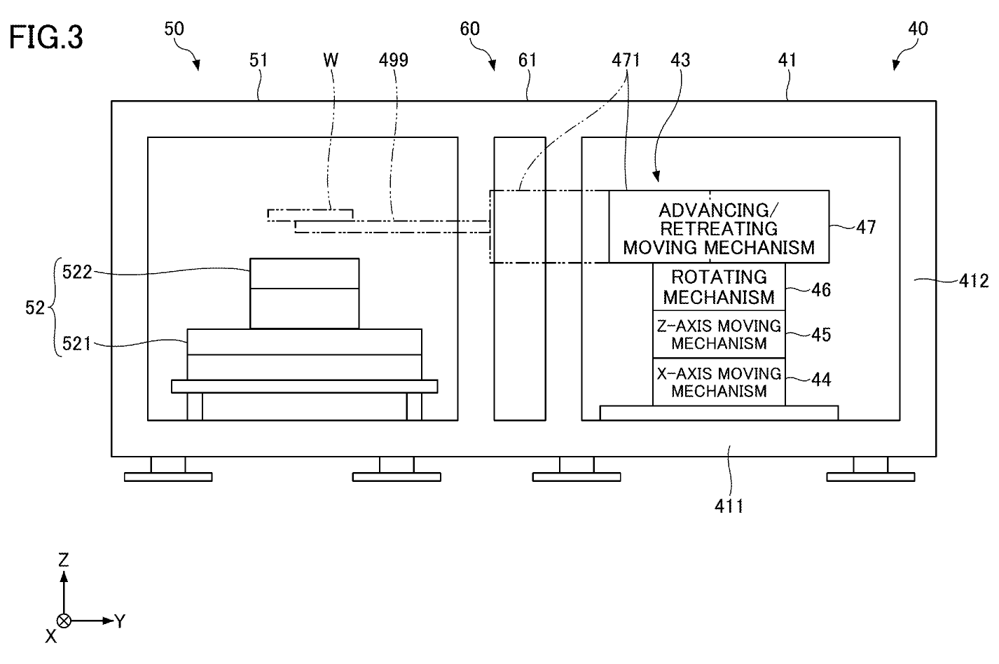

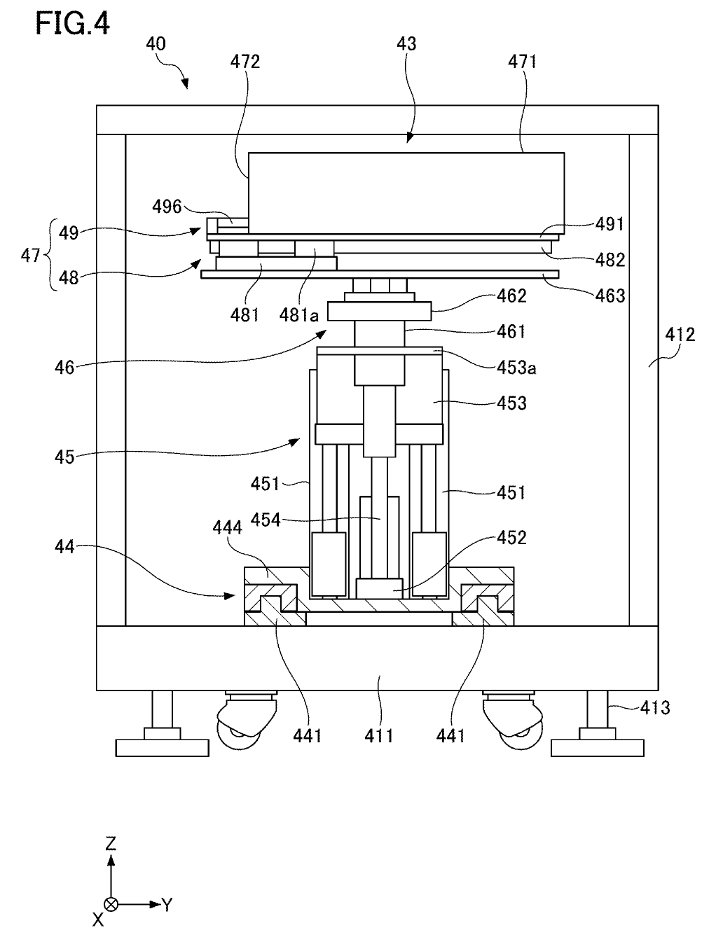

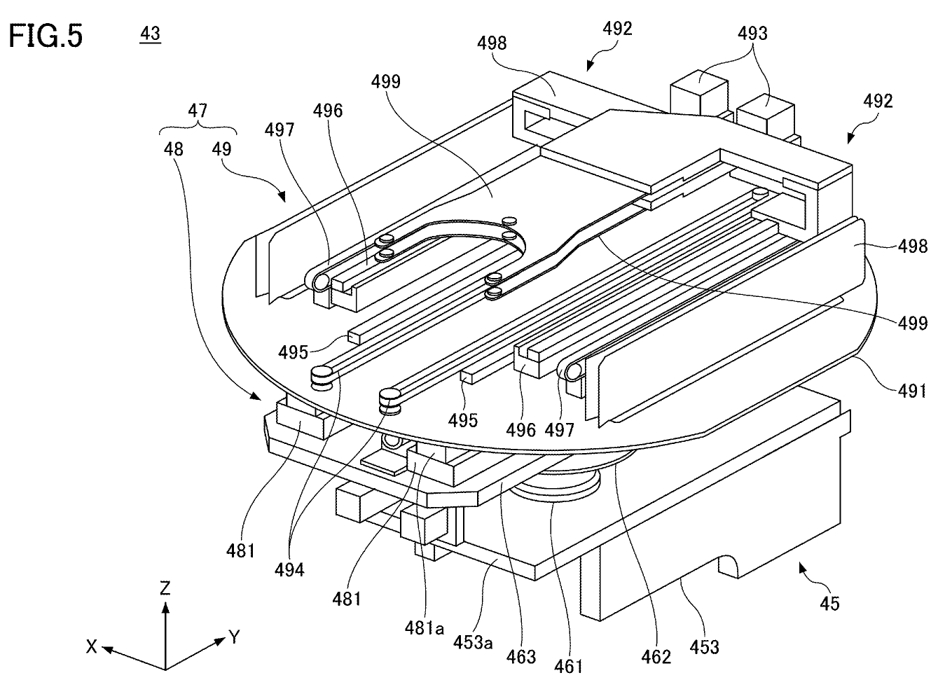

FIG. 3 is a schematic side view showing the installation state of the transport module 40 including the transport device 43 and the inspection device 50. FIG. 4 is an enlarged side view showing the transport device 43. The transport device 43 moves the transport housing 41 in the X-axis direction, the Z-axis direction (vertical direction), about the vertical axis, and in the Y-axis direction, to perform receiving, handing off, transporting, and the like of the substrate W. Specifically, the transport device 43 is provided with the above-described X-axis moving mechanism 44 at the lowermost part on the lower side of the transport device 43 in the vertical direction, and is provided with a Z-axis moving mechanism 45, a rotating mechanism 46, and an advancing/retreating moving mechanism 47 in this order from the X-axis moving mechanism 44 to the upper side in the vertical direction.

The Z-axis moving mechanism 45 employs a ball screw mechanism, a cylinder mechanism, and the like, and raises and lowers the rotating mechanism 46 and the advancing/retreating moving mechanism 47 provided above the Z-axis moving mechanism 45. For example, the Z-axis moving mechanism 45 includes a pair of elevating guides 451 and a drive motor 452 that are provided on the X-axis movable body 444, and a Z-axis movable body 453 that rises and lowers under drive of the drive motor 452 while bridging the pair of elevating guides 451.

The pair of elevating guides 451 extend in the vertical direction from the X-axis movable body 444, and each has a rail fixed to one surface thereof. The Z-axis movable body 453 is provided, on a surface thereof facing each elevating guide 451, with a slider (not shown) including a rolling body engaged with this rail and configured to roll on the rail. Thus, the Z-axis movable body 453 rises and lowers along the respective elevating guides 451. Further, the Z-axis movable body 453 includes a horizontal support plate 453a that extends in the X-axis negative direction from the respective elevating guides 451, and the rotating mechanism 46 is provided on the support plate 453a.

The drive motor 452 is connected to the controller 90 via a driver (not shown), and the drive force and the drive direction of the drive motor 452 are controlled by the controller 90. Further, a ball screw 454 that extends in the vertical direction and is threadedly engaged with the Z-axis movable body 453 is connected to the shaft of the drive motor 452. The Z-axis moving mechanism 45 raises and lowers the Z-axis movable body 453 in the vertical direction by the ball screw 454 rotating in accordance with the drive (forward rotation, reverse rotation) by the drive motor 452.

The rotating mechanism 46 is provided between the Z-axis moving mechanism 45 and the advancing/retreating moving mechanism 47, and rotates the advancing/retreating moving mechanism 47 relatively with respect to the Z-axis moving mechanism 45. The rotating mechanism 46 includes a drive motor 461 fixed to the support plate 453a of the Z-axis movable body 453, a disk 462 that rotates under the drive of the drive motor 461, and a rotating plate 463 connected to the disk 462. The drive motor 461 is connected to the controller 90 via a driver (not shown), and the drive force and the drive direction of the drive motor 461 are controlled by the controller 90.

The disk 462 and the rotating plate 463 are connected via a plurality of columns. Thus, the rotating plate 463 is supported in the horizontal direction and rotates about a vertical axis (θ axis) relative to the support plate 453a. The rotating plate 463 is formed in a rectangular shape in a plan view, and the advancing/retreating moving mechanism 47 is slidably mounted thereon.

By being installed on the rotating plate 463, the advancing/retreating moving mechanism 47 changes its orientation in the horizontal direction in accordance with the rotation angle of the rotating plate 463. For example, the rotating mechanism 46 rotates the advancing/retreating moving mechanism 47 over a range from the Y-axis positive direction side to the Y-axis negative direction side (180°). The rotating mechanism 46 may be configured to rotate the advancing/retreating moving mechanism 47 by 360° about a vertical axis.

The advancing/retreating moving mechanism 47 is a part for directly supporting the substrate W in the transport device 43 and transporting the substrate W to the inspection devices 50. The advancing/retreating moving mechanism 47 according to the embodiment is configured to slide by a plurality of stages in the same Y-axis direction. Thus, the advancing/retreating moving mechanism 47 can transport the substrate W over a long stroke.

Specifically, the advancing/retreating moving mechanism 47 includes a lower slider 48 installed on the rotating plate 463 and an upper slider 49 installed on the lower slider 48. The advancing/retreating moving mechanism 47 includes a cover 471 for covering the upper slider 49.

The lower slider 48 includes a pair of drive transmission parts 481 fixed to one end of the rotating plate 463 and a pair of movable rails 482 supporting the upper slider 49 and configured to slide by means of the drive transmission parts 481, respectively. The drive transmission parts 481 include drive sources (not shown) in parts thereof that are fixed to the rotating plate 463, and transmit the drive forces of the drive sources to the pair of movable rails 482 supported thereon. Examples of the drive transmission parts 481 include a linear motion structure composed of a rack and a pinion. The drive transmission parts 481 are connected to the controller 90 via a driver (not shown), and the drive force and the drive direction of the drive transmission parts 481 are controlled by the controller 90.

The pair of movable rails 482 are supported in parallel by a support 481a that is on the drive transmission parts 481, and extend in the horizontal direction. Each movable rail 482 moves linearly along its extending direction under the drive of the drive transmission part 481. As a result, the entirety of the upper slider 49 provided on each movable rail 482 slides in an appropriate direction.

The upper slider 49 includes a substantially circular floor plate 491 having a lower surface to which each movable rail 482 of the lower slider 48 is connected, and the upper surface side of the floor plate 491 is covered with the cover 471. The cover 471 is formed in a cylindrical shape having a large diameter in the horizontal direction and being short in the vertical direction, and has an opening part 472 in a part of the cover 471 in the circumferential direction. The upper slider 49 causes the substrate W to advance or retreat through the opening part 472 of the cover 471. The cover 471 may be provided with a purge pipe (not shown) to clean the substrate W by supplying inert gas, air, or the like into the cover 471 from the purge pipe.

FIG. 5 is an oblique view showing the advancing/retreating moving mechanism 47 of the transport device 43. FIG. 5 shows a state in which the cover 471 is removed for facilitating understanding. As shown in FIG. 5, the upper slider 49 of the advancing/retreating moving mechanism 47 includes a pair of arm mechanisms 492 that are installed on the upper surface of the floor plate 491. Each arm mechanism 492 includes a drive motor 493, a fixed drive transmission part 494, a fixed guide 495, a movable guide 496, a movable drive transmission part 497, a support arm 498, and an end effector 499.

Each drive motor 493 is installed at the other end (base end) of the floor plate 491 opposite to one end (leading end) side at which the end effector 499 is located. Each drive motor 493 is connected to the controller 90 (see FIG. 1) via a driver (not shown), and the drive of the drive motor 493 is controlled by the controller 90.

The fixed drive transmission part 494 transmits the drive force of the drive motor 493 to the movable guide 496, the movable drive transmission part 497, the support arm 498, and the end effector 499 to slide these members integrally. That is, the movable guide 496, the movable drive transmission part 497, the support arm 498, and the end effector 499 constitute a slide structure, and can reciprocate relative to the floor plate 491.

The fixed guide 495 is provided at a position adjacent to the fixed drive transmission part 494, and is fixed to the floor plate 491 and extends linearly. Thus, the fixed guide 495 guides the movement of the slide structure.

The movable guide 496 is spaced apart from the floor plate 491 and extends in parallel with the fixed guide 495. The movable guide 496 is caused to advance or retreat relatively to the fixed guide 495 by the fixed drive transmission part 494. The support arm 498 is slidably supported over the movable guide 496.

The movable drive transmission part 497 includes an endless belt extending in parallel with the movable guide 496, and the support arm 498 is engaged with the belt. The movable drive transmission part 497 internally includes a drive motor (not shown), and slides the support arm 498 relative to the movable guide 496 under the drive of the drive motor.

The support arm 498 includes a base part that is guided by the movable guide 496 and to which a drive force is applied by the movable drive transmission part 497, a projecting part erected in the vertical direction from the base part, and an upper part bent inward from the upper end of the projecting part. The upper part of the support arm 498 is formed in a letter-L shape bent in the direction toward the leading end in the center of the upper slider 49. The end effector 499 is connected to the leading end of the support arm 498.

The end effector 499 has a shape capable of supporting the substrate W. Specifically, the end effector 499 is configured in a letter-U shaped flat plate when viewed in a plan view, by having a base part connected to the support arm 498 and a fork extending from the base part in the direction toward the leading end in a bifurcated manner. Further, the end effector 499 includes contact pads that are configured to directly contact the substrate W, at suitable positions on the upper surface (the leading end of the base part and the pair of leading ends of the fork). The end effector 499 may have a fixing member for fixing the substrate W by suction, mechanical locking, and the like.

The pair of arm mechanisms 492 are formed linearly symmetrically with respect to the center line of the floor plate 491 in a plan view. The pair of arm mechanisms 492 have the upper parts of their support arms 498 and their end effectors 499 at different heights by being varied in the projection heights of their support arms 498. The pair of arm mechanisms 492 are configured such that the two end effectors 499 are stacked one above the other above the center line of the floor plate 491.

In each arm mechanism 492, the end effector 499 is located at a standby position above the floor plate 491 with the end effector 499 caused to retreat by the fixed drive transmission part 494 and the movable drive transmission part 497. In this case, each arm mechanism 492 is in a form of being housed within the cover 471 (see FIG. 3) in the entirety thereof. Then, by advancing the support arm 498 by the fixed drive transmission part 494 and the movable drive transmission part 497, each arm mechanism 492 advances the end effector 499 from the opening part 472 of the cover 471.

Referring back to FIG. 2, the transport device 43 may include a housing 70, which is a buffer configured to move integrally on the pair of rails 441 and temporarily house the substrate W. For example, the housing 70 is mounted on the X-axis movable body 444 of the X-axis moving mechanism 44, and disposed on the X-axis positive direction side of the advancing/retreating moving mechanism 47. The housing 70 has one or more ports 71 on a side surface of the housing 70 on the X-axis negative direction side, through which the substrate W can be loaded or unloaded. The transport device 43 rotates, and raises or lowers the advancing/retreating moving mechanism 47 to face the ports 71, and then advances the end effectors 499 of the upper slider 49, to thereby load and unload the substrate W into and from the housing 70 through the ports 71.

Further, the housing 70 may internally include an attitude adjusting device (aligner device: not shown) that adjusts the position and the attitude of the housed substrate W in cooperation with the transport device 43. By providing the attitude adjusting device at a position adjacent to the transport device 43 in this way, it is possible to shorten a time loss that might occur due to any misalignment or the like of the substrate W that requires the transport device 43 to move such that the aligner device 34 can adjust the misalignment of the substrate W. Alternatively, the substrate inspection unit 20 may be free of the aligner device 34 of the loader module 30.

Other than being configured to move integrally with the transport device 43, the housing 70 may be provided at an appropriate position in the transport module 40. For example, the transport module 40 may include the housing 70 at an end on the X-axis positive direction side (an end on the side opposite to the loader module 30).

The inspection device 50 connected to the transport module 40 inspects electrical characteristics of the substrate W transported by the transport module 40. The inspection device 50 includes an inspection device housing 51 (only the frame is shown in FIGS. 2 and 3), and a stage 52 for supporting the substrate W inside the inspection device housing 51. The stage 52 includes a moving part 521 for moving the substrate W to a target three-dimensional coordinate position, and a mounting table 522 for directly supporting the substrate W above the moving part 521. The moving part 521 moves the mounting table 522 in the X-axis direction, the Y-axis direction, and the Z-axis direction within the inspection device housing 51.

Further, as shown in FIG. 1, the inspection device 50 includes a tester 53 above the inspection device housing 51, which holds a probe card (not shown) including a plurality of probes to be in contact with the substrate W and is configured to inspect the substrate W. Further, the inspection device 50 includes a tester moving mechanism 54 for holding the tester 53 and moving the tester 53 between a test position (see the broken line in FIG. 1) and a retreated position (see the two-dot chain line in FIG. 1). A support table 55 for supporting the tester 53 is provided at the retreated position. Further, in the inspection device 50, various components, such as a chiller (not shown) for adjusting the temperature of the substrate W during an inspection, a suction mechanism (not shown) for reducing the pressure in the inspection device housing 51 during an inspection, and the like, are installed around the inspection device housing 51 and the tester moving mechanism 54.

The inspection device 50 is connected to the transport module 40 orthogonally (at an angle of 90°) via a connection buffer 60. The connection buffer 60 sets the inspection device housing 51 at a position away from the transport housing 41. In other words, the inspection device 50 determines its position in the Y-axis direction with respect to the transport module 40 by being connected to the transport module 40 via the connection buffer 60. Thus, the inspection device 50 can be installed without allowing the tester moving mechanism 54 and the like to interfere with the transport housing 41.

As shown in FIG. 2, the connection buffer 60 is configured by assembling a plurality of frames 61 and panels (not shown). The connection buffer 60 is formed in a rectangular parallelepiped larger in size than the upper slider 49 of the transport device 43 of the transport module 40, and allows the upper slider 49 to enter. Although not shown, a gate valve for closing the inspection device housing 51 may be provided inside the connection buffer 60.

As shown in FIGS. 2 and 3, the transport housing 41 of the transport module 40, the inspection device housing 51 of the inspection device 50, and the connection buffer 60 have their upper ends at the same height. The transport device 43 of the transport module 40 is configured to be lower in height than the upper end of the transport module 40, and can smoothly access the inspection device housing 51 through the connection buffer 60 that is at the same height as the inspection device housing 51.

In particular, since the transport device 43 is provided with the advancing/retreating moving mechanism 47 above the rotating mechanism 46, the advancing/retreating moving mechanism 47 can be brought to face the stages 52 of the inspection devices 50 connected to both sides of the transport module 40 (see also FIG. 1). When the rotating mechanism 46 is rotating, the advancing/retreating moving mechanism 47 has a compact structure by housing the end effectors 499 in the cover 471. Therefore, the transport device 43 can rotate the advancing/retreating moving mechanism 47 about the vertical axis while avoiding interference by the substrate W.

Referring back to FIG. 1, a computer including a processor, a memory, an input/output interface, a communication interface, and the like (not shown) is applied as the controller 90 of the substrate inspection unit 20. The processor is a combination of one or more selected from a Central Processing Unit (CPU), a Graphics Processing Unit (GPU), an Application Specific Integrated Circuit (ASIC), a Field-Programmable Gate Array (FPGA), a circuit composed of a plurality of discrete semiconductors, and the like, and executes and processes a program stored in the memory. The memory includes a main storage device composed of a semiconductor memory or the like, and an auxiliary storage device composed of a disk, a drive, a semiconductor memory (flash memory), or the like.

The transport system 1 according to the embodiment is basically configured as described above, and its operation will be described below. As shown in FIG. 1, the transport system 1 controls the hoist mechanism by means of the control device of the overhead hoist transport 10 to transport the carrier C and set the carrier C on the load port 31 of the target substrate inspection unit 20 (loader module 30). The controller 90 of the substrate inspection unit 20 acquires information indicating that the carrier C is set from the load port 31 on which the carrier C is set (or from the control device), and thereby shifts to the transporting of the substrate W in the substrate inspection unit 20.

Specifically, the controller 90 controls the loader-side transport device of the loader module 30 to take out the substrate W from the carrier C and transport it to the aligner device 34. The controller 90 controls the aligner device 34 and the loader-side transport device to adjust misalignment and the attitude of the substrate W. Thereafter, the controller 90 takes out the substrate W from the aligner device 34 by the loader-side transport device and transports the substrate W to the buffer 42 of the transport module 40. Thus, the controller 90 controls the transport module 40.

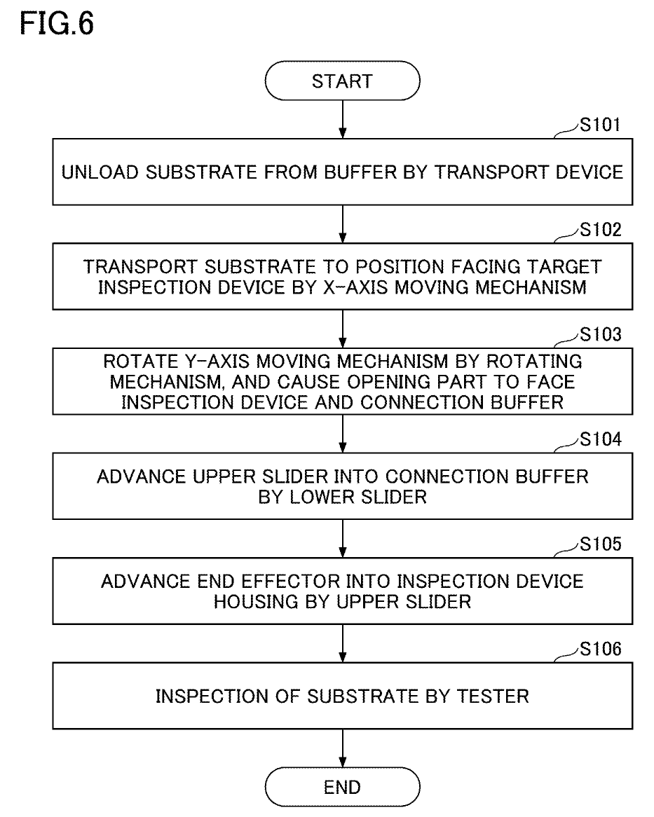

FIG. 6 is a flowchart showing a method of transporting the substrate W in the transport module 40. As shown in FIG. 6, after transporting the substrate W to the buffer 42, the controller 90 controls the transport device 43 of the transport module 40 to unload the substrate W from the buffer 42 by the transport device 43 (step S101). Here, the controller 90 moves the entirety of the transport device 43 to a position adjacent to the buffer 42 by the X-axis moving mechanism 44, and rotates the rotating mechanism 46 to cause the opening part 472 of the advancing/retreating moving mechanism 47 to face the buffer 42. In this state, the controller 90 advances the end effectors 499 of the upper slider 49 of the advancing/retreating moving mechanism 47 into the buffer 42, and raises or lowers a lifter (not shown) of the buffer 42 such that the substrate W is held on the end effectors 499. After the substrate W is held on the end effectors 499, the controller 90 causes the end effectors 499 to retreat to house the substrate W inside the cover 471.

Next, the controller 90 operates the X-axis moving mechanism 44 to transport the substrate W to a position facing the target inspection device 50 among the plurality of inspection devices 50 connected to the transport module 40 (step S102). During this movement, the end effectors 499 and the substrate W are housed in the cover 471. Therefore, the transport device 43 can transport the substrate W by reliably preventing interference or the like by the substrate W.

Further, the controller 90 rotates the rotating mechanism 46 at the position facing the target inspection device 50, thereby causing the opening part 472 of the advancing/retreating moving mechanism 47 to face the inspection device 50 and the connection buffer 60 (step S103). Here, in order to adjust the height of the stage 52 of the inspection device 50 to that of the advancing/retreating moving mechanism 47, the Z-axis moving mechanism 45 may raise or lower the advancing/retreating moving mechanism 47.

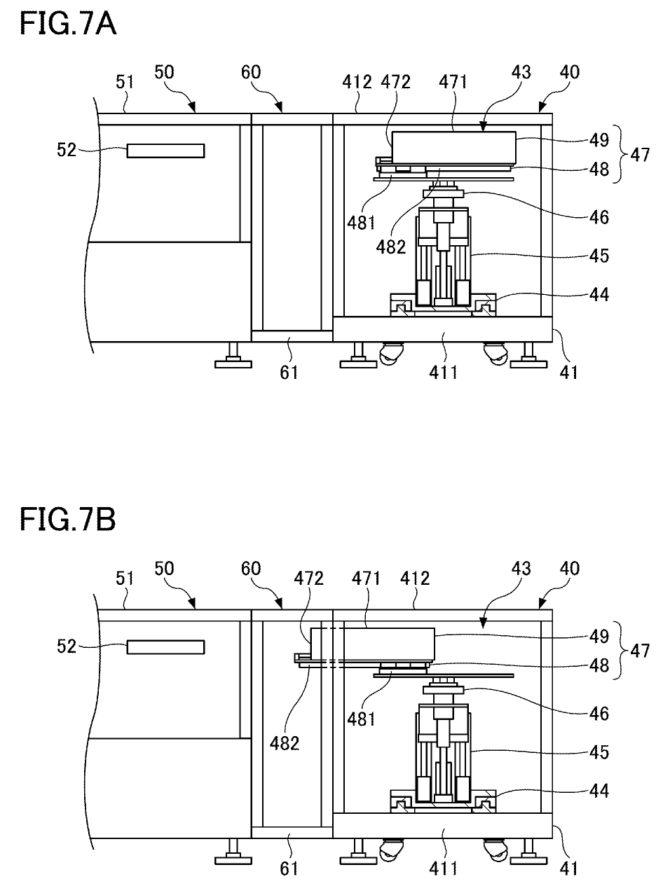

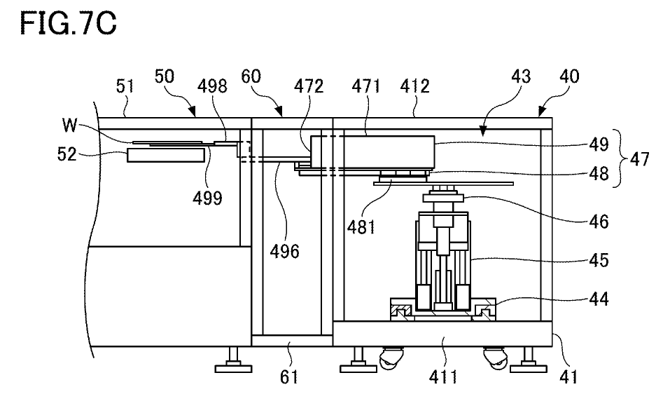

FIG. 7A is a side view showing a state in which the opening part 472 of the transport device 43 faces the target inspection device 50. FIG. 7B is a side view showing a state in which the lower slider 48 of the transport device 43 is advanced. FIG. 7C is a side view showing a state in which the end effectors 499 of the upper slider 49 of the transport device 43 are advanced. As shown in FIG. 7A, the transport device 43 is adjusted to an attitude in which the opening part 472 of the transport device 43 faces the top of the stage 52 of the inspection device 50, by the operation in step S103. Thereafter, the controller 90 operates the advancing/retreating moving mechanism 47 to advance the substrate W into the inspection device 50 and place the substrate W on the stage 52 of the inspection device 50.

Specifically, the controller 90 first operates the lower slider 48 to advance the upper slider 49 into the connection buffer 60 of the inspection device 50 (step S104). As shown in FIG. 7B, when moving the upper slider 49, the drive transmission parts 481 of the lower slider 48 move the movable rails 482 in the Y-axis negative direction. As a result, a part of the upper slider 49 including the cover 471 enters the connection buffer 60. The illustrated example shows a state in which the opening part 472 of the cover 471 is positioned in the connection buffer 60.

Further, the controller 90 moves the upper slider 49 to advance the end effectors 499 into the inspection device housing 51 of the inspection device 50 (step S105). As shown in FIG. 7C, the upper slider 49 moves the movable guides 496 and the movable drive transmission parts 497 relatively to the floor plate 491 by the drive of the drive motors 493. Further, the upper slider 49 moves the support arms 498 and the end effectors 499 relatively to the movable guides 496 by the movable drive transmission parts 497.

By these steps S104 and S105, the total length of the advancing/retreating moving mechanism 47 along the Y-axis direction becomes sufficiently long, and the substrate W supported on the end effectors 499 can reliably reach the stage 52 of the inspection device 50. Then, by raising or lowering the lifter (not shown) of the stage 52 of the inspection device 50, the controller 90 can cause the stage 52 to receive the substrate W from the end effectors 499 and have the substrate W mounted thereon. The order of the operations of the lower slider 48 and the upper slider 49 is not limited to the above, and the upper slider 49 may be operated first and the lower slider 48 may be operated next, or the lower slider 48 and the upper slider 49 may be operated simultaneously.

After the substrate W is mounted, the controller 90 operates the tester 53 of the inspection device 50 to inspect the substrate W by the tester 53 (step S106). The inspection device 50 can stably inspect the substrate W by the tester 53 because the substrate W is mounted on the stage 52 with accuracy by the transport device 43.

After inspecting the substrate W, the controller 90 unloads the substrate W from the inspection device 50 and transports the substrate W to the buffer 42 by reversely following the procedure for loading the substrate W by the transport device 43. Further, the controller 90 operates the loader-side transport device to receive the substrate W from the buffer 42 and transport the substrate W to an appropriate carrier C. As a result, the inspection of the substrate W by the substrate inspection unit 20 is completed.

The substrate inspection unit 20 repeats inspection by transporting the plurality of substrates W housed in the carrier C to the inspection devices 50 respectively, thereby housing the inspected substrates W in the carriers C. The control device of the overhead hoist transport 10 controls the hoist mechanism to hold the carriers C housing the plurality of inspected substrates W, raise (release) the carriers C from the substrate inspection unit 20, and transport the carriers C along the rail 11.

As described above, since the transport system 1 has the advancing/retreating moving mechanism 47 having the 2-stage structure including the lower slider 48 and the upper slider 49, it is possible to favorably transport the substrate W even into the inspection device 50 spaced from the transport module 40 by the connection buffer 60. Moreover, in the standby state of the lower slider 48 and the upper slider 49, the transport device 43 is in a compact form and can perform movement in the X-axis direction, rotation about the vertical axis, movement in the Z-axis direction, and the like easily.

The transport system 1 and the transport method according to the embodiment are not limited to the embodiment described above, and various modifications can be employed. For example, in the embodiment, the transport system 1 in which the substrate inspection unit 20 including the plurality of inspection devices 50 serving as processing modules is disposed has been described. However, in the transport system 1, a substrate processing unit including substrate processing devices may be applied instead of a subset or all of the substrate inspection units 20. Examples of the substrate processing devices include processing modules for performing substrate processing such as film formation, etching, cleaning, bonding, peeling, and the like on the substrate W. The substrate processing devices may be devices, such as a repair device, a marking device, a reflow device, an appearance inspection device, and the like for processing the substrate W in the post-steps after the substrate W is manufactured. In other words, the transport system 1 can be applied as a configuration for transporting the substrate W to processing modules for performing various actions on the substrate W in the process of manufacturing the substrate W.

Furthermore, the transport target to be transported by the transport system is not limited to the substrate W, and may be, for example, a probe card, a polishing plate, and the like. Furthermore, the transport target may be a consumable member applied to a processing module. Examples of the consumable member include rings (a focus ring, an edge ring, and the like) disposed around the substrate W in a processing module.

The technical concept and effects of the present disclosure explained in the above embodiments will be described below.

A first aspect of the present disclosure is the transport system 1 including: the transport module 40 extending in the first direction; the plurality of processing modules (the inspection devices 50) connected to the transport module 40; and the transport device 43 provided inside the transport module 40 and configured to transport a transport target (a substrate W) to the plurality of processing modules, wherein the transport device 43 includes: the moving mechanism (the X-axis moving mechanism 44) configured to move a transport target along the first direction; the lower slider 48 provided above the moving mechanism in the vertical direction and capable of moving the transport target in the second direction different from the first direction; and the upper slider 49 provided above the lower slider 48 in the vertical direction and capable of moving the transport target in the second direction.

According to the above, the transport system 1 can move the transport target (the substrate W) in the second direction by the lower slider 48 and the upper slider 49, separately, and can move the transport target over a long stroke. In addition, when not moving the lower slider 48 and the upper slider 49, by maintaining them in a mutually stacked state, it is possible to promote size reduction of the transport device 43 while avoiding interference of the transport target with other components.

Further, the plurality of processing modules (the inspection devices 50) have their positions in the second direction with respect to the transport module 40 defined by being connected to the transport module 40 via the connection buffers 60. Thus, even when connecting a large processing module to the transport module 40, it can be installed at an appropriate position in the transport system 1 with a margin secured by the connection buffer 60.

Further, the lower slider 48 moves the upper slider 49 into the connection buffer 60, and the upper slider 49 includes the end effectors 499 for supporting the transport target (the substrate W) and moving into the processing module (the inspection device 50) from the position at which the upper slider 49 is disposed by the lower slider 48. Thus, the transport system 1 can advance the end effectors 499 from the upper slider 49 disposed in the connection buffer 60, thereby enabling the substrate W to easily reach the processing module.

Further, the lower slider 48 includes the movable rails 482 that support the upper slider 49, and the drive transmission parts 481 that support the movable rails 482 and move the movable rails 482. Thus, the lower slider 48 can smoothly move the upper slider 49 along a horizontal direction.

Further, the upper slider 49 includes the support arms 498 for supporting the end effectors 499, the movable drive transmission parts 497 for moving the support arms 498 in the second direction, the movable guides 496 for guiding the movement of the support arms 498 in the second direction, the fixed drive transmission parts 494 for moving the movable guides 496 and the movable drive transmission parts 497 in the second direction, and the fixed guides 495 for guiding the movement of the movable guides 496 and the movable drive transmission parts 497 in the second direction. Thus, the upper slider 49 can advance the movable guides 496 and the movable drive transmission parts 497, and further advance the support arms 498 and the end effectors 499.

Further, the transport device 43 includes an elevating mechanism (the Z-axis moving mechanism 45) for raising and lowering the lower slider 48 and the upper slider 49 between the moving mechanism (the X-axis moving mechanism 44) and the lower slider 48. Thus, the transport device 43 can easily adjust the heights of the lower slider 48 and the upper slider 49.

Further, the transport device 43 includes the rotating mechanism 46 for rotating the lower slider 48 and the upper slider 49 about the vertical axis between the elevating mechanism (the Z-axis moving mechanism 45) and the lower slider 48. The rotating mechanism 46 enables the transport device 43 to appropriately adjust the advancing direction of the lower slider 48 and the upper slider 49.

Further, the plurality of processing modules (the inspection devices 50) are provided on both side surfaces of the transport module 40 in the first direction, and the rotating mechanism 46 rotates the lower slider 48 and the upper slider 49 over a range of 180° or greater. Thus, even when the plurality of processing modules are arranged on both side surfaces of the transport module 40, the transport system 1 can transport the transport target to the processing modules, and the footprint of the entire transport system 1 can be improved.

Further, the transport module 40 internally includes the buffers (the buffer 42 and the housing 70) for temporarily holding the transport target. Thus, the transport system 1 can temporarily hold the substrate W in the transport module 40, and the moving distance of the transport device 43 can be shortened. For example, even in a sequence in which the transport device 43 would be unable to go to receive a substrate W because of holding another substrate W, it is possible to transport a plurality of substrates W by using the buffers, and to prevent transport rate limiting.

Further, the buffer (the housing 70) moves integrally with the transport device 43 by means of the moving mechanism (the X-axis moving mechanism 44). Thus, the transport system 1 can hold the transport target near the transport device 43, and can realize efficient transport by reducing movement of the transport device 43 in the X-axis direction.

Further, the buffers (the buffer 42 and the housing 70) include aligner devices capable of adjusting misalignment and the circumferential-direction orientation of the transport target. Thus, the transport system 1 can adjust the misalignment and the circumferential-direction orientation of the transport target in the transport module 40 without a return to the aligner device 34 in the loader module 30, thereby improving the transporting efficiency while improving transport target-transporting accuracy.

Further, the transport module 40 and the plurality of processing modules (the inspection device 50) are at the same height in the vertical direction. Thus, the transport system 1 can reduce operations performed by the transport device 43 for adjusting the height in the vertical direction, and more smoothly transport the transport target to the processing modules. Further, for example, by using the transport module 40 having the uniform height even for an inspection device 50 using a large-sized tester 53, it is possible to maintain the design of the transport device 43 with a long stroke and to omit changes in the device layout.

A second aspect of the present disclosure is a transport method of a transport system 1 including: the transport module 40 extending in the first direction; the plurality of processing modules (the inspection devices 50) connected to the transport module 40; and the transport device 43 provided inside the transport module 40 and configured to transport the transport target to the plurality of processing modules, the transport method including: (A) moving the transport target along the first direction by the moving mechanism (the X-axis moving mechanism 44), and positioning the transport device 43 at a position facing one processing module of the plurality of processing modules; (B) moving the transport target in the second direction different from the first direction by the lower slider 48 provided above the moving mechanism in the vertical direction; and (C) moving the transport target in the second direction by the upper slider 49 provided above the lower slider 48 in the vertical direction. Also in this case, it is possible to move the transport target over a long stroke while promoting size reduction of the transport device 43.

The transport system 1 and the transport method according to the embodiments disclosed herein are exemplary and not restrictive in all respects. The embodiments can be modified and improved in various forms without departing from the scope and the spirit of the appended claims. The particulars described in the above embodiments can be constructed in other ways to the extent that no contradiction would occur and can be combined to the extent that no contradiction would occur.

According to one aspect, it is possible to move a transport target over a long stroke while promoting size reduction of the transport device.

What is claimed is:

1. A transport system, comprising:
a transport module extending in a first direction;
a plurality of processing modules connected to the transport module; and
a transport device provided inside the transport module and configured to transport a transport target to the plurality of processing modules,
wherein the transport device includes:
a moving mechanism configured to move the transport target along the first direction;
a lower slider provided above the moving mechanism in a vertical direction and capable of moving the transport target in a second direction different from the first direction; and
an upper slider provided above the lower slider in the vertical direction and capable of moving the transport target in the second direction.

2. The transport system according to claim 1,
wherein each of the plurality of processing modules determines its position in the second direction with respect to the transport module by being connected to the transport module via a connection buffer.

3. The transport system according to claim 2,
wherein the lower slider moves the upper slider into the connection buffer, and
the upper slider includes an end effector configured to support the transport target and move into the plurality of processing modules from a position at which the upper slider is disposed by the lower slider.

4. The transport system according to claim 3,
wherein the lower slider includes:
a movable rail configured to support the upper slider; and
a drive transmission part configured to support the movable rail and move the movable rail.

5. The transport system according to claim 3,
wherein the upper slider includes:
a support arm configured to support the end effector;
a movable drive transmission part configured to move the support arm in the second direction;
a movable guide configured to guide movement of the support arm in the second direction;
a fixed drive transmission part configured to move the movable guide and the movable drive transmission part in the second direction; and
a fixed guide configured to guide movement of the movable guide and the movable drive transmission part in the second direction.

6. The transport system according to claim 1,
wherein the transport device includes an elevating mechanism configured to raise and lower the lower slider and the upper slider, the elevating mechanism being disposed between the moving mechanism and the lower slider.

7. The transport system according to claim 6,
wherein the transport device includes a rotating mechanism configured to rotate the lower slider and the upper slider about a vertical axis, the rotating mechanism being disposed between the elevating mechanism and the lower slider.

8. The transport system according to claim 7,
wherein the plurality of processing modules are provided on both side surfaces of the transport module in the first direction, and
the rotating mechanism is configured to rotate the lower slider and the upper slider over a range of 180° or greater.

9. The transport system according to claim 1,
wherein the transport module internally includes a buffer configured to temporarily hold the transport target.

10. The transport system according to claim 9,
wherein the buffer moves integrally with the transport device by means of the moving mechanism.

11. The transport system according to claim 9,
wherein the buffer includes an aligner device capable of adjusting misalignment and a circumferential-direction orientation of the transport target.

12. The transport system according to claim 1,
wherein the transport module and the plurality of processing modules are at a same height in the vertical direction.

13. A transport method of a transport system,
the transport system including:
a transport module extending in a first direction;
a plurality of processing modules connected to the transport module; and
a transport device provided inside the transport module and configured to transport a transport target to the plurality of processing modules,
the transport method comprising:
(A) moving the transport target along the first direction by a moving mechanism, and positioning the transport device at a position facing one processing module of the plurality of processing modules;
(B) moving the transport target in a second direction different from the first direction by a lower slider provided above the moving mechanism in a vertical direction; and
(C) moving the transport target in the second direction by an upper slider provided above the lower slider in the vertical direction.
